(19) United States
(12) Patent Application Publication
(10) Pub. No.: US 2020/0402438 A1
(43) Pub. Date: Dec. 24, 2020

(54) SHIFT REGISTER AND METHOD OF DRIVING THE SAME, GATE DRIVING CIRCUIT AND DISPLAY APPARATUS

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Yongxian Xie, Beijing (CN); Hui Wang, Beijing (CN); Fengzhen Lv, Beijing (CN); Ran Zhang, Beijing (CN); Cilong Luo, Beijing (CN); Ruiying Yang, Beijing (CN)

(21) Appl. No.: 16/969,648

(22) PCT Filed: Dec. 20, 2019
(86) PCT No.: PCT/CN2019/127093

§ 371 Date: Aug. 13, 2020

(30) Foreign Application Priority Data
Jan. 28, 2019 (CN) 201910080262.6

(51) Int. Cl. G09G 3/20; G11C 19/28

(52) U.S. Cl. CPC G09G 3/20; G11C 19/28; G09G 2300/08; G09G 2310/0286; G09G 2300/0426; G09G 2310/0267; G09G 2310/08

(57) ABSTRACT

The present disclosure provides a shift register and a method of driving the same, a gate driving circuit, and a display apparatus. The shift register includes an input circuit, an output circuit, a reset circuit, a control circuit, and a pull-down circuit. The control circuit is configured to, in response to a potential at the pull-up node, transmit a reference signal received at a reference signal terminal to a first pull-down node and/or a second pull-down node under control of a first control signal received at a first control signal terminal and a second control signal received at a second control signal terminal.

### CROSS-REFERENCE TO RELATED APPLICATION(S)

This application is a Section 371 National Application of International Application No. PCT/CN2019/127093, filed on Dec. 20, 2019, entitled “SHIFT REGISTER AND METHOD OF DRIVING THE SAME, GATE DRIVING CIRCUIT AND DISPLAY APPARATUS”, which published as WO 2020/155920 A1, on Aug. 6, 2020, which claims priority to the Chinese Patent Application No. 201910080262.6, filed on Jan. 28, 2019, the disclosures of which are incorporated herein by reference in their entireties.

### TECHNICAL FIELD

The present disclosure relates to the field of display, and more particularly, to a shift register and a method of driving the same, a gate driving circuit and a display apparatus.

### BACKGROUND

Gate On Array (GOA) is a technology which integrates a gate driving circuit on a thin film transistor substrate. Each GOA unit serves as a shift register to sequentially transfer a scanning signal to a next GOA unit, to cause switches of the thin film transistor substrate to be turned on progressively, and complete input of data signals to pixel units.

Dual-VDD direct-current GOA architecture has been widely used in conventional GOA products due to its stable de-noising capability.

### SUMMARY

According to an embodiment of the present disclosure, there is provided a shift register. The shift register comprises:
an input circuit coupled to a signal input terminal and a pull-up node of the shift register, and configured to transmit an input signal received at the signal input terminal to the pull-up node;
an output circuit coupled to a first signal output terminal and a clock signal terminal, and configured to transmit a clock signal received at the clock signal terminal to the first signal output terminal in response to a potential at the pull-up node;
a reset circuit coupled to a first reset signal terminal, a reference signal terminal and the pull-up node, and configured to transmit a reference signal at the reference signal terminal to the pull-up node under control of a first reset signal received at the first reset signal terminal;
a control circuit coupled to the pull-up node, the reference signal terminal, a first power supply signal terminal, a second power supply signal terminal, a first control signal terminal and a second control signal terminal, and configured to transmit the reference signal received at the reference signal terminal to a first pull-down node and/or a second pull-down node of the shift register under control of a first control signal received at the first control signal terminal and a second control signal received at the second control signal terminal in response to the potential at the pull-up node; and
a pull-down circuit coupled to the first pull-down node and the second pull-down node, and configured to transmit the reference signal at the reference signal terminal to the pull-up node in response to potentials at the first pull-down node and the second pull-down node.

In some embodiments, the control circuit comprises:
a first control sub-circuit coupled to the first power supply signal terminal, the pull-up node and the first pull-down node, and configured to control the potential at the first pull-down node based on the first power supply signal received at the first power supply signal terminal in response to the potential at the pull-up node;
a second control sub-circuit coupled to the second power supply signal terminal, the pull-up node and the second pull-down node, and configured to control the potential at the second pull-down node based on the second power supply signal received at the second power supply signal terminal in response to the potential at the pull-up node; and
an adjustment sub-circuit coupled to the first control signal terminal, the second control signal terminal, the first pull-down node, the second pull-down node and the reference signal terminal, and configured to transmit the reference signal received at the reference signal terminal to the first pull-down node under control of the first control signal received at the first control signal terminal, and transmit the reference signal received at the reference signal terminal to the second pull-down node under control of the second control signal received at the second control signal terminal.

In some embodiments, the adjustment sub-circuit comprises:
a first transistor having a control electrode coupled to the first control signal terminal, a first electrode coupled to the first pull-down node, and a second electrode coupled to the reference signal terminal; and
a second transistor having a control electrode coupled to the second control signal terminal, a first electrode coupled to the second pull-down node, and a second electrode coupled to the reference signal terminal.

In some embodiments, the first control signal terminal is coupled to the second power supply signal terminal, and the second control signal terminal is coupled to the first power supply signal terminal.

In some embodiments, the first control signal terminal and the second control signal terminal are coupled to each other.

In some embodiments, the first control sub-circuit comprises a third transistor and a fourth transistor, and the second control sub-circuit comprises a fifth transistor and a sixth transistor, wherein
the third transistor has a control electrode coupled to the first power supply signal terminal, a first electrode coupled to the first power supply signal terminal, and a second electrode coupled to the first pull-down node;
the fifth transistor has a control electrode coupled to the second power supply signal terminal, a first electrode coupled to the second power supply signal terminal, and a second electrode coupled to the second pull-down node;
the fourth transistor has a control electrode coupled to the pull-up node, a first electrode coupled to the first pull-down node, and a second electrode coupled to the reference signal terminal; and
the sixth transistor has a control electrode coupled to the pull-up node, a first electrode coupled to the second pull-down node, and a second electrode coupled to the reference signal terminal.

In some embodiments, the first control sub-circuit comprises a third transistor, a fourth transistor, a seventh transistor, and an eighth transistor, and the second control sub-circuit comprises a fifth transistor, a sixth transistor, a ninth transistor and a tenth transistor, wherein
the third transistor has a control electrode coupled to the first power supply signal terminal, a first electrode coupled to the first power supply signal terminal, and a second electrode coupled to a first electrode of the fourth transistor;
the fifth transistor has a control electrode coupled to the second power supply signal terminal, a first electrode coupled to the second power supply signal terminal, and a second electrode coupled to a first electrode of the sixth transistor;
the fourth transistor has a control electrode coupled to the pull-up node, a first electrode coupled to the second electrode of the third transistor, and a second electrode coupled to the reference signal terminal;
the sixth transistor has a control electrode coupled to the pull-up node, a first electrode coupled to the second electrode of the fifth transistor, and a second electrode coupled to the reference signal terminal;
the seventh transistor has a control electrode coupled to the second electrode of the third transistor, a first electrode coupled to the first power supply signal terminal, and a second electrode coupled to the first pull-down node;
the ninth transistor has a control electrode coupled to the second electrode of the fifth transistor, a first electrode coupled to the second power supply signal terminal, and a second electrode coupled to the second pull-down node;
the eighth transistor has a control electrode coupled to the pull-up node, a first electrode coupled to the first pull-down node, and a second electrode coupled to the reference signal terminal; and
the tenth transistor has a control electrode coupled to the pull-up node, a first electrode coupled to the second pull-down node, and a second electrode coupled to the reference signal terminal.

In some embodiments, the pull-down circuit comprises an eleventh transistor, a twelfth transistor, a thirteenth transistor, and a fourteenth transistor, wherein
the eleventh transistor has a control electrode coupled to the first pull-down node, a first electrode coupled to the pull-up node, and a second electrode coupled to the reference signal terminal;
the twelfth transistor has a control electrode coupled to the second pull-down node, a first electrode coupled to the pull-up node, and a second electrode coupled to the reference signal terminal;
the thirteenth transistor has a control electrode coupled to the first pull-down node, a first electrode coupled to the first signal output terminal, and a second electrode coupled to the reference signal terminal; and
the fourteenth transistor has a control electrode coupled to the second pull-down node, a first electrode coupled to the first signal output terminal, and a second electrode coupled to the reference signal terminal.

In some embodiments, the pull-down circuit comprises an eleventh transistor, a twelfth transistor, a thirteenth transistor, a fourteenth transistor, a fifteenth transistor, and a sixteenth transistor, wherein
the eleventh transistor has a control electrode coupled to the first pull-down node, a first electrode coupled to the pull-up node, and a second electrode coupled to the reference signal terminal;
the twelfth transistor has a control electrode coupled to the second pull-down node, a first electrode coupled to the pull-up node, and a second electrode coupled to the reference signal terminal;
the thirteenth transistor has a control electrode coupled to the first pull-down node, a first electrode coupled to the first signal output terminal, and a second electrode coupled to the reference signal terminal;
the fourteenth transistor has a control electrode coupled to the second pull-down node, a first electrode coupled to the first signal output terminal, and a second electrode coupled to the reference signal terminal;
the fifteenth transistor has a control electrode coupled to the first pull-down node, a first electrode coupled to a second signal output terminal of the shift register unit, and a second electrode coupled to the reference signal terminal; and
the sixteenth transistor has a control electrode coupled to the second pull-down node, a first electrode coupled to the second signal output terminal, and a second electrode coupled to the reference signal terminal.

In some embodiments, the reset circuit comprises a seventeenth transistor and an eighteenth transistor, wherein,
the seventeenth transistor has a control electrode coupled to the first reset signal terminal, a first electrode coupled to the pull-up node, and a second electrode coupled to the reference signal terminal; and
the eighteenth transistor has a control electrode coupled to the first reset signal terminal, a first electrode coupled to the first signal output terminal, and a second electrode coupled to the reference signal terminal.

In some embodiments, the reset circuit comprises a seventeenth transistor having a control electrode coupled to the first reset signal terminal, a first electrode coupled to the pull-up node, and a second electrode coupled to the reference signal terminal.

In some embodiments, the reset circuit comprises a seventeenth transistor, a nineteenth transistor, and a twentieth transistor, wherein
the seventeenth transistor has a control electrode coupled to the first reset signal terminal, a first electrode coupled to the pull-up node, and a second electrode coupled to the reference signal terminal;
the nineteenth transistor has a control electrode coupled to the second reset signal terminal, a first electrode coupled to the pull-up node, and a second electrode coupled to the reference signal terminal; and
the twentieth transistor has a control electrode coupled to the second reset signal terminal, a first electrode coupled to the first signal output terminal, and a second electrode coupled to the reference signal terminal.

In some embodiments, the reset circuit comprises a seventeenth transistor and a nineteenth transistor, wherein
the seventeenth transistor has a control electrode coupled to the first reset signal terminal, a first electrode coupled to the pull-up node, and a second electrode coupled to the reference signal terminal; and
the nineteenth transistor has a control electrode coupled to the second reset signal terminal, a first electrode coupled to the pull-up node, and a second electrode coupled to the reference signal terminal.

In some embodiments, the input circuit comprises a twenty-first transistor having a control electrode coupled to a signal input terminal, a first electrode coupled to the signal input terminal, and a second electrode coupled to the pull-up node.

In some embodiments, the output circuit comprises a twenty-second transistor and a capacitor, wherein
the twenty-second transistor has a control electrode coupled to the pull-up node, a first electrode coupled to the clock signal terminal, and a second electrode coupled to the first signal output terminal; and
the capacitor has a first terminal coupled to the pull-up node, and a second terminal coupled to the first signal output terminal.

In some embodiments, the output circuit comprises a twenty-second transistor, a twenty-third transistor, and a capacitor, wherein
the twenty-second transistor has a control electrode coupled to the pull-up node, a first electrode coupled to the clock signal terminal, and a second electrode coupled to the first signal output terminal;
the twenty-third transistor has a control electrode coupled to the pull-up node, a first electrode coupled to the clock signal terminal, and a second electrode coupled to the second signal output terminal of the shift register; and
the capacitor has a first terminal coupled to the pull-up node, and a second terminal coupled to the first signal output terminal.

According to another embodiment of the present disclosure, there is provided a gate driving circuit, comprising a plurality of cascaded shift registers described above.

According to yet another embodiment of the present disclosure, there is provided a display apparatus comprising the gate driving circuit described above.

According to still another embodiment of the present disclosure, there is provided a method of driving the shift register described above, comprising:
transmitting, by the input circuit, the input signal received at the signal input terminal to the pull-up node;
in response to the potential at the pull-up node, transmitting, by the output circuit, the clock signal received at the clock signal terminal to the first signal output terminal;
in response to the potential at the pull-up node, transmitting, by the control circuit, a first level of the reference signal to the first pull-down node and/or the second pull-down node under control of the first control signal and the second control signal;
in response to the potentials at the first pull-down node and the second pull-down node, transmitting, by the pull-down circuit, the reference signal at the reference signal terminal to the pull-up node; and
transmitting, by the reset circuit, the reference signal at the reference signal terminal to the pull-up node under control of the first reset signal received at the first reset signal terminal.

In some embodiments, the first control signal received at the first control signal terminal is the second power supply signal received at the second power supply signal terminal, and the second control signal received at the second control signal terminal is the first power supply signal received at the first power supply signal terminal.

In some embodiments, the first control signal received at the first control signal terminal and the second control signal received at the second control signal terminal are both a third reset signal.

In some embodiments, an effective level of the third reset signal occurs before the start of each frame.

In some embodiments, an effective level of the third reset signal occurs in response to transition of the first power supply signal or the second power supply signal.

### BRIEF DESCRIPTION OF THE ACCOMPANYING DRAWINGS

FIG. 1(a) illustrates an exemplary circuit diagram of a shift register in the related art;

FIG. 1(b) illustrates a schematic block diagram of a shift register according to an embodiment of the present disclosure;

FIG. 1(c) illustrates a schematic block diagram of a shift register according to another embodiment of the present disclosure;

FIG. 2 illustrates a schematic circuit diagram of a shift register according to an embodiment of the present disclosure;

FIG. 3 illustrates a schematic circuit diagram of a shift register according to another embodiment of the present disclosure;

FIG. 4 illustrates a schematic circuit diagram of a shift register according to yet another embodiment of the present disclosure;

FIG. 5 illustrates a schematic circuit diagram of a shift register according to yet another embodiment of the present disclosure;

FIG. 6 illustrates a schematic flowchart of a method of driving a shift register according to an embodiment of the present disclosure;

FIG. 7(a) illustrates a schematic operation timing diagram of the shift register in FIG. 1(a);

FIG. 7(b) illustrates a schematic operation timing diagram of the shift register in FIG. 2;

FIG. 7(c) illustrates another schematic operation timing diagram of the shift register in FIG. 2;

FIG. 7(d) illustrates another schematic operation timing diagram of the shift register in FIG. 2; and

FIG. 8 illustrates a schematic block diagram of a display apparatus according to an embodiment of the present disclosure.

### DETAILED DESCRIPTION

In order to make the purposes, technical solutions and advantages of the embodiments of the present disclosure more clear, the technical solutions in the embodiments of the present disclosure will be clearly and completely described below in conjunction with the accompanying drawings in the embodiments of the present disclosure. Obviously, the embodiments described are a part of the embodiments of the present disclosure instead of all the embodiments. All other embodiments obtained by those of ordinary skill in the art based on the described embodiments of the present disclosure without contributing any creative work are within the protection scope of the present disclosure. It should be illustrated that throughout the accompanying drawings, the same elements are represented by the same or similar reference signs. In the following description, some specific embodiments are for illustrative purposes only and are not to be construed as limiting the present disclosure, but merely examples of the embodiments of the present disclosure. The conventional structure or construction will be omitted when it may cause confusion with the understanding of the present disclosure. It should be illustrated that shapes and dimensions of components in the figures do not reflect true sizes and proportions, but only illustrate contents of the embodiments of the present disclosure.

Unless otherwise defined, technical terms or scientific terms used in the embodiments of the present disclosure should be of ordinary meanings to those skilled in the art. “First”, “second” and similar words used in the embodiments of the present disclosure do not represent any order, quantity or importance, but are merely used to distinguish between different constituent parts.

Furthermore, in the description of the embodiments of the present disclosure, the term “coupled with” or “coupled to” may mean that two components are directly coupled, or that two components are coupled via one or more other components. In addition, the two components may be connected or coupled by wire or wirelessly.

In addition, in the description of the embodiments of the present disclosure, terms “first level” and “second level” are only used to distinguish magnitudes of the two levels from each other. For example, description is made below by taking the “first level” being a low level and the “second level” being a high level as an example. It may be understood by those skilled in the art that the present disclosure is not limited thereto.

The transistors used in the embodiments of the present disclosure may each be a thin film transistor or a field effect transistor or other devices having the same characteristics. In one embodiment, the thin film transistors used in the embodiments of the present disclosure may be oxide semiconductor transistors. Since a source and a drain of the thin film transistor used herein are symmetrical, the source and the drain thereof may be interchanged. In the embodiments of the present disclosure, one of the source and the drain is referred to as a first electrode, and the other of the source and the drain is referred to as a second electrode. In the following example, N-type thin film transistors are taken as an example for description. It may be understood by those skilled in the art that the embodiments of the present disclosure may obviously be applied to a case of P-type thin film transistors.

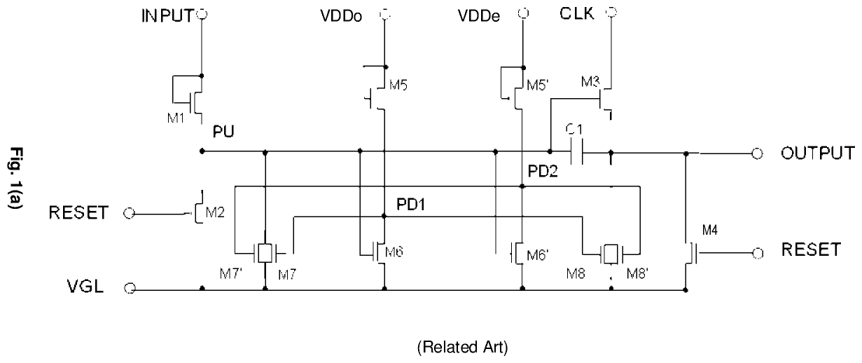

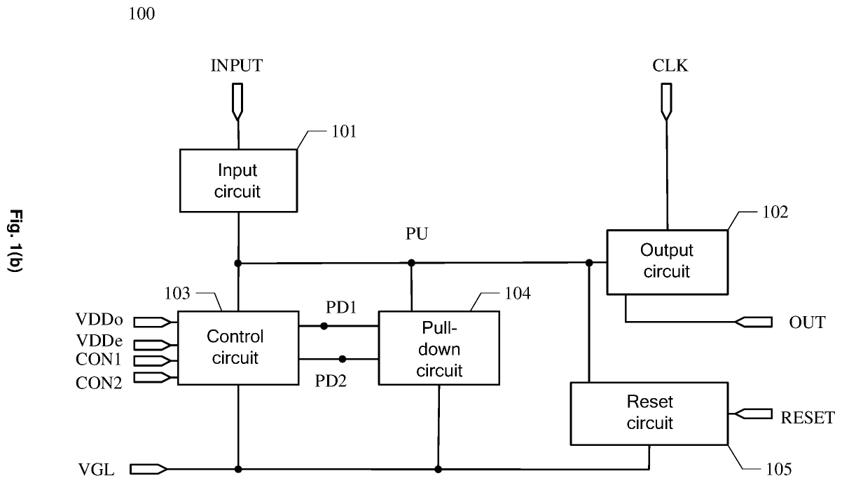

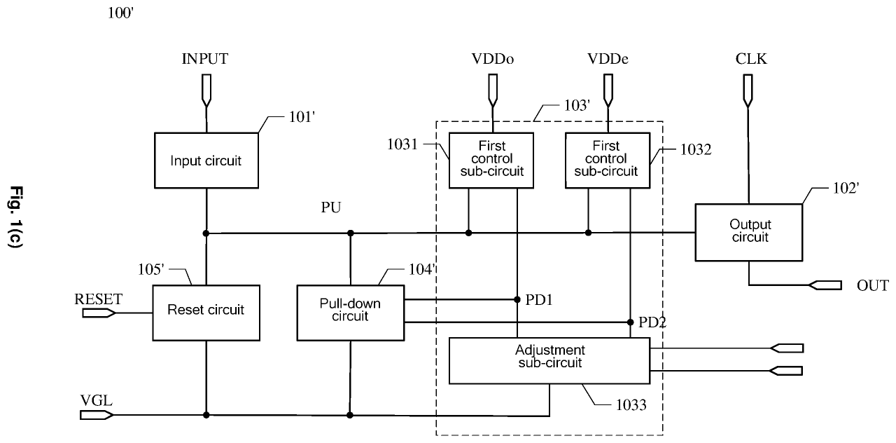

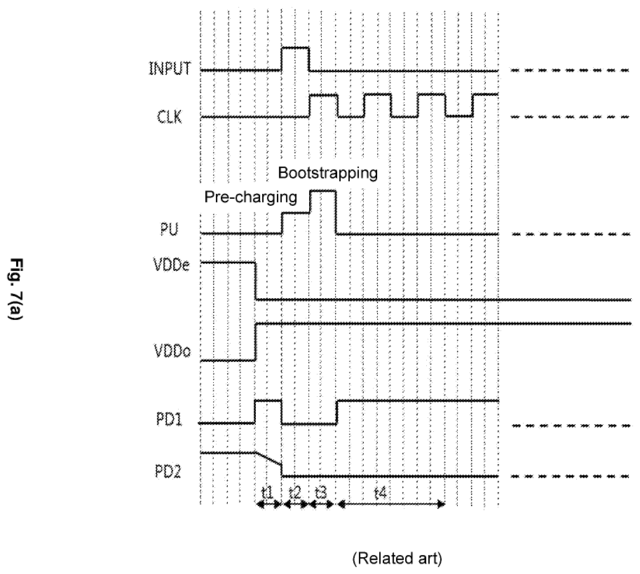

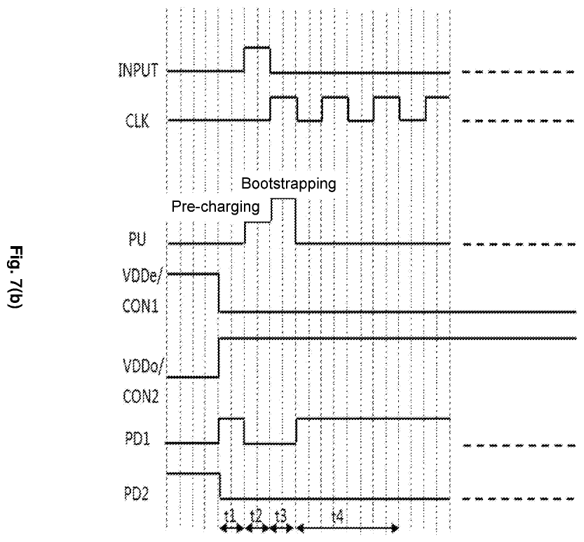

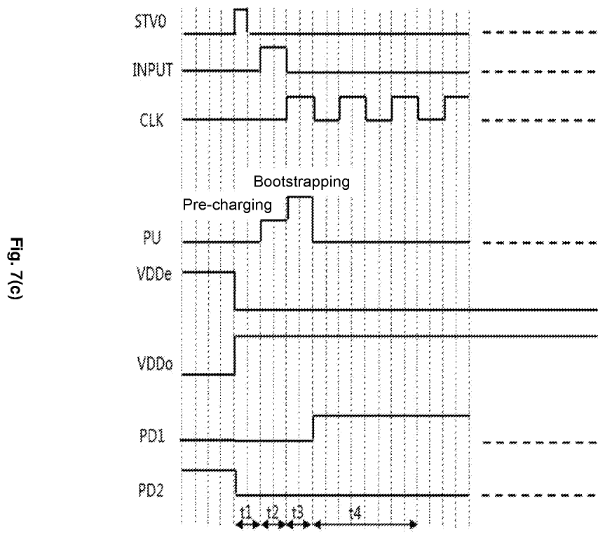

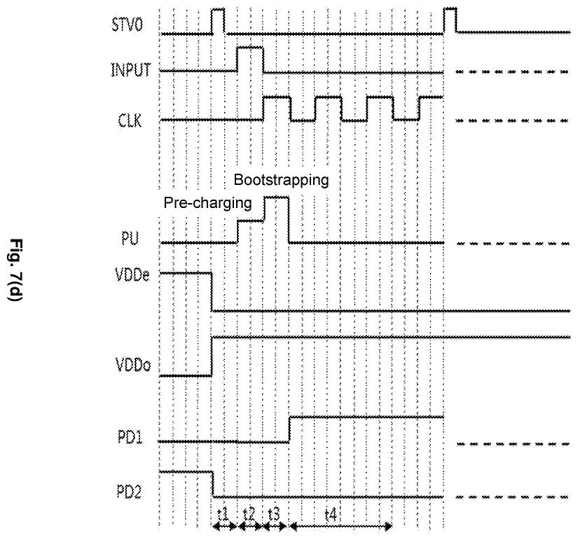

FIG. 1(a) illustrates an exemplary circuit diagram of a dual-VDD direct-current GOA unit (i.e., a shift register) in the related art. As shown in FIG. 1(a), the GOA unit comprises two direct-current power supply signal terminals VDDe and VDDo, which are used to receive two power supply signals respectively. One of the two power supply signals is at a high level, and the other of the two power supply signals is at a low level, wherein the high-level voltage signal may provide a discharging signal for the GOA unit. Generally, the two signals may be switched at predetermined time intervals (for example, every two seconds) and the switching is configured to be performed when a node PU is at a low level (in a case where a transistor is, for example, an N-type transistor). When the power supply signal terminal VDDe changes from a high level to a low level and at the same time the power supply signal terminal VDDo changes from a low level to a high level, a transistor M5 is turned on, a transistor M5′ is turned off, current is leaked from a node PD2 through the transistors M5′ and M6′ and the node PD2 slowly decreases to a level of a power supply signal VGL, and in contrast, a node PD1 is quickly pulled up, as shown by the nodes PD1 and PD2 during a period t1 in FIG. 7(a). In this way, within a period of time (for example, t1 in FIG. 7(a)) after the power supply signals VDDo and VDDe are switched, the nodes PD1 and PD2 are both at a high level, so that transistors M7 and M7′ are both turned on (however, it is actually expected that when the node PD1 is at a high level, the node PD2 is pulled down to the level of the power supply signal VGL, so that only one of the transistors M7 and M7′ is turned on or both of the transistors M7 and M7′ are turned off). In this way, when the node PU is charged, large discharging current passes through the transistors M7 and M7′, which affects the charging of the node PU. Similarly, when the power supply signal VDDo changes from a high level to a low level and the power supply signal VDDe changes from a low level to a high level, there is the same problem.

The shift register and the method of driving the same, the gate driving circuit and the display apparatus according to the embodiments of the present disclosure may enable at least one of a first pull-down node and a second pull-down node to be reset to a level at a reference signal terminal more quickly than the conventional technology when a first power supply signal and a second power supply signal are switched, thereby preventing the slow charging of one of the first pull-down node and the second pull-down node from affecting the charging of a pull-up node.

FIG. 1(b) illustrates a schematic block diagram of a shift register 100 according to an embodiment of the present disclosure.

As shown in FIG. 1(b), the shift register 100 may comprise an input circuit 101. The input circuit 101 may be coupled to a signal input terminal INPUT and a pull-up node PU, and may be configured to transmit an input signal received at the signal input terminal INPUT to the pull-up node PU.

The shift register 100 may comprise an output circuit 102. The output circuit 102 may be coupled to a first signal output terminal OUT and a clock signal terminal CLK, and may be configured to transmit a clock signal received at the clock signal terminal CLK to the first signal output terminal OUT in response to a potential at the pull-up node PU.

The shift register 100 may comprise a control circuit 103. The control circuit 103 may be coupled to the pull-up node PU, a reference signal terminal VGL, a first power supply signal terminal VDDo, a second power supply signal terminal VDDe, a first control signal terminal CON1 and a second control signal terminal CON2, and may be configured to transmit a reference signal received at the reference signal terminal VGL to a first pull-down node PD1 and/or second pull-down node PD2 under control of a first control signal received at the first control signal terminal CON1 and a second control signal received at the second control signal terminal CON2 in response to the potential at the pull-up node PU.

In one embodiment, the reference signal received at the reference signal terminal VGL may always be maintained at a first level, a first power supply signal received at the first power supply signal terminal VDDo and a second power supply signal received at the second power supply signal terminal VDDe may be signals which are switched between the first level and a second level, for example, periodic pulse signals. This enables the first power supply signal to be at the first level and enables the second power supply signal to be at the second level during a first time period; and enables the first power supply signal to be at the second level and enables the second power supply signal to be at the first level during a second time period. The first power supply signal and the second power supply signal may have the same period and the same amplitude, but have opposite phases. The periods of the first power supply signal and the second power supply signal may be, for example, 2 seconds, or any suitable time. According to the present disclosure, switching of the two power supply signals means that while one power supply signal changes from the first level to the second level, the other power supply signal changes from the second level to the first level.

In one embodiment, the first control signal terminal CON1 may be coupled to the second power supply signal terminal VDDe, and the second control signal terminal CON2 may be coupled to the first power supply signal terminal VDDo. This enables the first control signal received at the first control signal terminal CON1 to be the second power supply signal received at the second power supply signal terminal VDDe, and enables the second control signal received at the second control signal terminal CON2 to be the first power supply signal received at the first power supply signal terminal VDDo.

In one embodiment, the first control signal terminal CON1 and the second control signal terminal CON2 may be coupled to receive the same signal (for example, a third reset signal), which enables the first control signal received at the first control signal terminal CON1 and the second control signal received at the second control signal terminal CON2 to be both the third reset signal. The third reset signal is used to reset the first pull-down node PD1 and the second pull-down node PD2, for example, pull down the first pull-down node PD1 and the second pull-down node PD2 to a low level. In some embodiments, an effective level of the third reset signal may occur before the start of each frame. In some other embodiments, the effective level of the third reset signal may occur in response to transition of the first power supply signal or the second power supply signal. For example, this enables the third reset signal to trigger the resetting of the first pull-down node PD1 and the second pull-down node PD2 before the start of each frame, or may trigger the resetting of the first pull-down node PD1 and the second pull-down node PD2 in response to the transition (at, for example, a rising edge or a falling edge) of the first power supply signal or the second power supply signal. That is, a period of the third reset signal may be the same as that of the first power supply signal or the second power supply signal, or may be the same as a period of the frame.

The shift register 100 may comprise a pull-down circuit 104. The pull-down circuit 104 may be coupled to the first pull-down node PD1 and the second pull-down node PD2, and may be configured to transmit the reference signal at the reference signal terminal VGL to the pull-up node PU in response to the potentials at the first pull-down node PD1 and the second pull-down node PD2.

The shift register 100 may comprise a reset circuit 105. The reset circuit 105 may be coupled to a first reset signal terminal RESET, the reference signal terminal VGL and the pull-up node PU, and may be configured to transmit the reference signal at the reference signal terminal VGL to the pull-up node PU under control of a first reset signal received at the first reset signal terminal RESET.

The shift register according to the present disclosure may enable at least one of the first pull-down node and the second pull-down node to be quickly reset to the level (for example, the first level) at the reference signal terminal when the first power supply signal and the second power supply signal are switched, thereby preventing the slow charging of a certain one of the first pull-down node and the second pull-down node from affecting the charging of the pull-up node.

FIG. 1(c) illustrates a schematic block diagram of a shift register according to another embodiment of the present disclosure.

Similarly to FIG. 1(b), the shift register 100′ shown in FIG. 1(c) comprises an input circuit 101′, an output circuit 102′, a control circuit 103′, a pull-down circuit 104′, and a reset circuit 105′. The above description of the input circuit, the output circuit, the control circuit, the pull-down circuit, and the reset circuit with reference to FIG. 1(b) is also applicable to the shift register 100′, and will not be repeated here.

As shown in FIG. 1(c), the control circuit 103′ comprises a first control sub-circuit 1031, a second control sub-circuit 1032, and an adjustment sub-circuit 1033.

The first control sub-circuit 1031 is coupled to the first power supply signal terminal VDDo, the pull-up node PU and the first pull-down node PD1. The first control sub-circuit 1031 may control the potential at the first pull-down node PD1 based on the first power supply signal received at the first power supply signal terminal VDDo in response to the potential at the pull-up node PU.

The second control sub-circuit 1032 is coupled to the second power supply signal terminal VDDe, the pull-up node PU and the second pull-down node PD2. The second control sub-circuit 1032 may control the potential at the second pull-down node PD2 based on the second power supply signal received at the second power supply signal terminal VDDe in response to the potential at the pull-up node PU.

The adjustment sub-circuit 1033 is coupled to the first control signal terminal CON1, the second control signal terminal CON2, the first pull-down node PD1, the second pull-down node PD2, and the reference signal terminal VGL. The adjustment sub-circuit 1033 may transmit the reference signal received at the reference signal terminal VGL to the first pull-down node PD1 under control of the first control signal received at the first control signal terminal CON1, and transmit the reference signal received at the reference signal terminal VGL to the second pull-down node PD2 under control of the second control signal received at the second control signal terminal CON2.

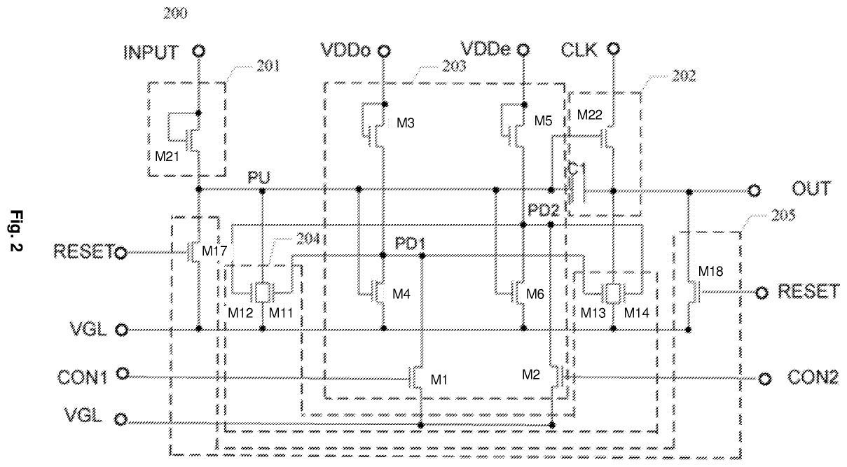

FIG. 2 illustrates a schematic circuit diagram of a shift register 200 according to an embodiment of the present disclosure.

As shown in FIG. 2, the shift register 200 may comprise an input circuit 201. The input circuit 201 may comprise a twenty-first transistor M21. The twenty-first transistor M21 has a control electrode coupled to the signal input terminal INPUT, a first electrode coupled to the signal input terminal INPUT, and a second electrode coupled to the pull-up node PU.

The shift register 200 may further comprise an output circuit 202. The output circuit 202 may comprise a twenty-second transistor M22 and a capacitor C1. The twenty-second transistor M22 has a control electrode coupled to the pull-up node PU, a first electrode coupled to the clock signal terminal CLK, and a second electrode coupled to the first signal output terminal OUT. The capacitor C1 has a first terminal coupled to the pull-up node PU, and a second terminal coupled to the first signal output terminal OUT.

The shift register 200 may further comprise a control circuit 203. The control circuit 203 may comprise a first control sub-circuit, a second control sub-circuit, and an adjustment sub-circuit. The first control sub-circuit may comprise a third transistor M3 and a fourth transistor M4. The second control sub-circuit may comprise a fifth transistor M5 and a sixth transistor M6. The adjustment sub-circuit may comprise a first transistor M1 and a second transistor M2. The third transistor M3 has a control electrode coupled to the first power supply signal terminal VDDo, a first electrode coupled to the first power supply signal terminal VDDo, and a second electrode coupled to the first pull-down node PD1. The fifth transistor M5 has a control electrode coupled to the second power supply signal terminal VDDe, a first electrode coupled to the second power supply signal terminal VDDe, and a second electrode coupled to the second pull-down node PD2. The fourth transistor M4 has a control electrode coupled to the pull-up node PU, a first electrode coupled to the first pull-down node PD1, and a second electrode coupled to the reference signal terminal VGL. The sixth transistor M6 has a control electrode coupled to the pull-up node PD1, a first electrode coupled to the second pull-down node PD2, and a second electrode coupled to the reference signal terminal VGL. The first transistor M1 has a control electrode coupled to the first control signal terminal CON1, a first electrode coupled to the first pull-down node PD1, and a second electrode coupled to the reference signal terminal VGL. The second transistor M2 has a control electrode coupled to the second control signal terminal CON2, a first electrode coupled to the second pull-down node PD2, and a second electrode coupled to the reference signal terminal VGL.

The shift register 200 may further comprise a pull-down circuit 204. The pull-down circuit 204 may comprise an eleventh transistor M11, a twelfth transistor M12, a thirteenth transistor M13, and a fourteenth transistor M14. The eleventh transistor M11 has a control electrode coupled to the first pull-down node PD1, a first electrode coupled to the pull-up node PU, and a second electrode coupled to the reference signal terminal VGL. The twelfth transistor M12 has a control electrode coupled to the second pull-down node PD2, a first electrode coupled to the pull-up node PU, and a second electrode coupled to the reference signal terminal VGL. The thirteenth transistor M13 has a control electrode coupled to the first pull-down node PD1, a first electrode coupled to the first signal output terminal OUT, and a second electrode coupled to the reference signal terminal VGL. The fourteenth transistor M14 has a control electrode coupled to the second pull-down node PD2, a first electrode coupled to the first signal output terminal OUT, and a second electrode coupled to the reference signal terminal VGL.

The shift register 200 may further comprise a reset circuit 205. The reset circuit 205 may comprise a seventeenth transistor M17 and an eighteenth transistor M18. The seventeenth transistor M17 has a control electrode coupled to the first reset signal terminal RESET, a first electrode coupled to the pull-up node PU, and a second electrode coupled to the reference signal terminal VGL. The eighteenth transistor M18 has a control electrode coupled to the first reset signal terminal RESET, a first electrode coupled to the first signal output terminal OUT, and a second electrode coupled to the reference signal terminal VGL.

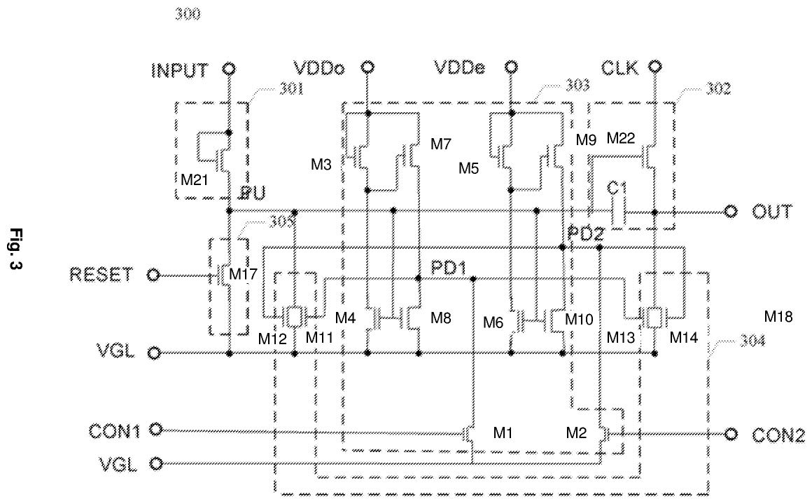

FIG. 3 illustrates a schematic circuit diagram of a shift register 300 according to another embodiment of the present disclosure.

As shown in FIG. 3, the shift register 300 may comprise an input circuit 301. The input circuit 301 may comprise a twenty-first transistor M21. The twenty-first transistor M21 has a control electrode coupled to the signal input terminal INPUT, a first electrode coupled to the signal input terminal INPUT, and a second electrode coupled to the pull-up node PU.

The shift register 300 may further comprise an output circuit 302. The output circuit 302 may comprise a twenty-second transistor M22 and a capacitor C1. The twenty-second transistor M22 has a control electrode coupled to the pull-up node PU, a first electrode coupled to the clock signal terminal CLK, and a second electrode coupled to the first signal output terminal OUT. The capacitor C1 has a first terminal coupled to the pull-up node PU, and a second terminal coupled to the first signal output terminal OUT.

The shift register 300 may further comprise a control circuit 303. The control circuit 303 may comprise a first control sub-circuit, a second control sub-circuit, and an adjustment sub-circuit. The first control sub-circuit may comprise a third transistor M3, a fourth transistor M4, a seventh transistor M7, and an eighth transistor M8. The second control sub-circuit may comprise a fifth transistor M5, a sixth transistor M6, a ninth transistor M9, and a tenth transistor M10. The adjustment sub-circuit may comprise a first transistor M1 and a second transistor M2. The third transistor M3 has a control electrode coupled to the first power supply signal terminal VDDo, a first electrode coupled to the first power supply signal terminal VDDo, and a second electrode coupled to a first electrode of the fourth transistor M4. The fifth transistor M5 has a control electrode coupled to the second power supply signal terminal VDDe, a first electrode coupled to the second power supply signal terminal VDDe, and a second electrode coupled to a first electrode of the sixth transistor M6. The fourth transistor M4 has a control electrode coupled to the pull-up node PU, a first electrode coupled to the second electrode of the third transistor M3, and a second electrode coupled to the reference signal terminal VGL. The sixth transistor M6 has a control electrode coupled to the pull-up node PU, a first electrode coupled to the second electrode of the fifth transistor M5, and a second electrode coupled to the reference signal terminal VGL. The first transistor M1 has a control electrode coupled to the first control signal terminal CON1, a first electrode coupled to the first pull-down node PD1, and a second electrode coupled to the reference signal terminal VGL. The second transistor M2 has a control electrode coupled to the second control signal terminal CON2, a first electrode coupled to the second pull-down node PD2, and a second electrode coupled to the reference signal terminal VGL. The seventh transistor M7 has a control electrode coupled to the second electrode of the third transistor M3, a first electrode coupled to the first power supply signal terminal VDDo, and a second electrode coupled to the first pull-down node PD1. The ninth transistor M9 has a control electrode coupled to the second electrode of the fifth transistor M5, a first electrode coupled to the second power supply signal terminal VDDe, and a second electrode coupled to the second pull-down node PD2. The eighth transistor M8 has a control electrode coupled to the pull-up node PU, a first electrode coupled to the first pull-down node PD1, and a second electrode coupled to the reference signal terminal VGL. The tenth transistor M10 has a control electrode coupled to the pull-up node PU, a first electrode coupled to the second pull-down node PD2, and a second electrode coupled to the reference signal terminal VGL.

The shift register 300 may further comprise a pull-down circuit 304. The pull-down circuit 304 may comprise an eleventh transistor M11, a twelfth transistor M12, a thirteenth transistor M13, and a fourteenth transistor M14. The eleventh transistor M11 has a control electrode coupled to the first pull-down node PD1, a first electrode coupled to the pull-up node PU, and a second electrode coupled to the reference signal terminal VGL. The twelfth transistor M12 has a control electrode coupled to the second pull-down node PD2, a first electrode coupled to the pull-up node PU, and a second electrode coupled to the reference signal terminal VGL. The thirteenth transistor M13 has a control electrode coupled to the first pull-down node PD1, a first electrode coupled to the first signal output terminal OUT, and a second electrode coupled to the reference signal terminal VGL. The fourteenth transistor M14 has a control electrode coupled to the second pull-down node PD2, a first electrode coupled to the first signal output terminal OUT, and a second electrode coupled to the reference signal terminal VGL.

The shift register 300 may further comprise a reset circuit 305. The reset circuit 305 may comprise a seventeenth transistor M17. The seventeenth transistor M17 has a control electrode coupled to the first reset signal terminal RESET, a first electrode coupled to the pull-up node PU, and a second electrode coupled to the reference signal terminal VGL.

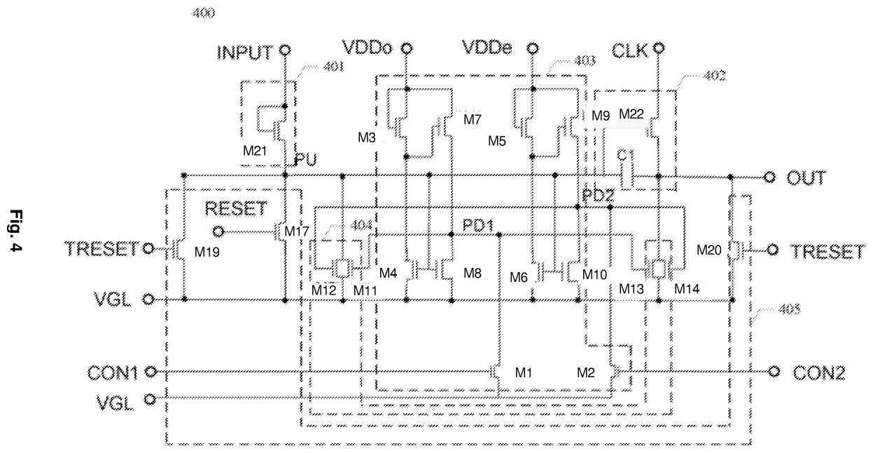

FIG. 4 illustrates a schematic circuit diagram of a shift register 400 according to yet another embodiment of the present disclosure.

As shown in FIG. 4, the shift register 400 may comprise an input circuit 401. The input circuit 401 may comprise a twenty-first transistor M21. The twenty-first transistor M21 has a control electrode coupled to the signal input terminal INPUT, a first electrode coupled to the signal input terminal INPUT, and a second electrode coupled to the pull-up node PU.

The shift register 400 may further comprise an output circuit 402. The output circuit 402 may comprise a twenty-second transistor M22 and a capacitor C1. The twenty-second transistor M22 has a control electrode coupled to the pull-up node PU, a first electrode coupled to the clock signal terminal CLK, and a second electrode coupled to the first signal output terminal OUT. The capacitor C1 has a first terminal coupled to the pull-up node PU, and a second terminal coupled to the first signal output terminal OUT.

The shift register 400 may further comprise a control circuit 403. The control circuit 403 may comprise a first control sub-circuit, a second control sub-circuit, and an adjustment sub-circuit. The first control sub-circuit may comprise a third transistor M3, a fourth transistor M4, a seventh transistor M7, and an eighth transistor M8. The second control sub-circuit may comprise a fifth transistor M5, a sixth transistor M6, a ninth transistor M9, and a tenth transistor M10. The adjustment sub-circuit may comprise a first transistor M1 and a second transistor M2. The third transistor M3 has a control electrode coupled to the first power supply signal terminal VDDo, a first electrode coupled to the first power supply signal terminal VDDo, and a second electrode coupled to a first electrode of the fourth transistor M4. The fifth transistor M5 has a control electrode coupled to the second power supply signal terminal VDDe, a first electrode coupled to the second power supply signal terminal VDDe, and a second electrode coupled to a first electrode of the sixth transistor M6. The fourth transistor M4 has a control electrode coupled to the pull-up node PU, a first electrode coupled to the second electrode of the third transistor M3, and a second electrode coupled to the reference signal terminal VGL. The sixth transistor M6 has a control electrode coupled to the pull-up node PU, a first electrode coupled to the second electrode of the fifth transistor M5, and a second electrode coupled to the reference signal terminal VGL. The first transistor M1 has a control electrode coupled to the first control signal terminal CON1, a first electrode coupled to the first pull-down node PD1, and a second electrode coupled to the reference signal terminal VGL. The second transistor M2 has a control electrode coupled to the second control signal terminal CON2, a first electrode coupled to the second pull-down node PD2, and a second electrode coupled to the reference signal terminal VGL. The seventh transistor M7 has a control electrode coupled to the second electrode of the third transistor M3, a first electrode coupled to the first power supply signal terminal VDDo, and a second electrode coupled to the first pull-down node PD1. The ninth transistor M9 has a control electrode coupled to the second electrode of the fifth transistor M5, a first electrode coupled to the second power supply signal terminal VDDe, and a second electrode coupled to the second pull-down node PD2. The eighth transistor M8 has a control electrode coupled to the pull-up node PU, a first electrode coupled to the first pull-down node PD1, and a second electrode coupled to the reference signal terminal VGL. The tenth transistor M10 has a control electrode coupled to the pull-up node PU, a first electrode coupled to the second pull-down node PD2, and a second electrode coupled to the reference signal terminal VGL.

The shift register 400 may further comprise a pull-down circuit 404. The pull-down circuit 404 may comprise an eleventh transistor M11, a twelfth transistor M12, a thirteenth transistor M13, and a fourteenth transistor M14. The eleventh transistor M11 has a control electrode coupled to the first pull-down node PD1, a first electrode coupled to the pull-up node PU, and a second electrode coupled to the reference signal terminal VGL. The twelfth transistor M12 has a control electrode coupled to the second pull-down node PD2, a first electrode coupled to the pull-up node PU, and a second electrode coupled to the reference signal terminal VGL. The thirteenth transistor M13 has a control electrode coupled to the first pull-down node PD1, a first electrode coupled to the first signal output terminal OUT, and a second electrode coupled to the reference signal terminal VGL. The fourteenth transistor M14 has a control electrode coupled to the second pull-down node PD2, a first electrode coupled to the first signal output terminal OUT, and a second electrode coupled to the reference signal terminal VGL.

The shift register 400 may further comprise a reset circuit 405. The reset circuit 405 may comprise a seventeenth transistor M17, a nineteenth transistor M19 and a twentieth transistor M20. The seventeenth transistor M17 has a control electrode coupled to the first reset signal terminal RESET, a first electrode coupled to the pull-up node PU, and a second electrode coupled to the reference signal terminal VGL. The nineteenth transistor M19 has a control electrode coupled to a second reset signal terminal TRESET, a first electrode coupled to the pull-up node PU and a second electrode coupled to the reference signal terminal VGL. The twentieth transistor M20 has a control electrode coupled to the second reset signal terminal TRESET, a first electrode coupled to the first signal output terminal OUT, and a second electrode coupled to the reference signal terminal VGL. In the reset circuit 405, in order to enhance the de-noising of the pull-up node PU and the first signal output terminal OUT, the second reset signal at the second reset signal terminal TRESET is used for de-noising shift registers corresponding to all rows at the end of each frame. Differently from the second reset signal at the second reset signal terminal TRESET, the first reset signal at the first reset signal terminal RESET is used to pull down the pull-up node PU and the first signal output terminal OUT of the shift register after the output of the shift register is completed, so as to prevent display confusion due to the clock signal at the clock signal terminal CLK being continuously output to the first signal output terminal OUT.

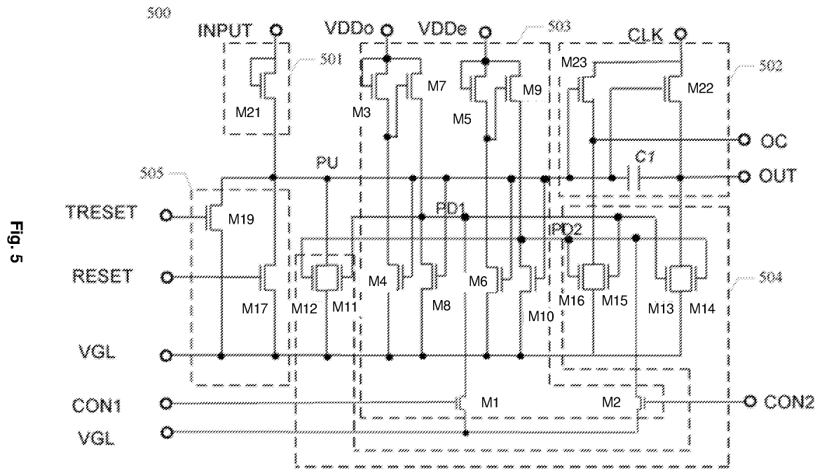

FIG. 5 illustrates a schematic circuit diagram of a shift register 500 according to yet another embodiment of the present disclosure.

As shown in FIG. 5, the shift register 500 may comprise an input circuit 501. The input circuit 501 may comprise a twenty-first transistor M21. The twenty-first transistor M21 has a control electrode coupled to the signal input terminal INPUT, a first electrode coupled to the signal input terminal INPUT, and a second electrode coupled to the pull-up node PU.

The shift register 500 may further comprise an output circuit 502. The output circuit 502 may comprise a twenty-second transistor M22, a twenty-third transistor M23, and a capacitor C1. The twenty-second transistor M22 has a control electrode coupled to the pull-up node PU, a first electrode coupled to the clock signal terminal CLK, and a second electrode coupled to the first signal output terminal OUT. The twenty-third transistor M23 has a control electrode coupled to the pull-up node PU, a first electrode coupled to the clock signal terminal CLK, and a second electrode coupled to the second signal output terminal OC. The capacitor C1 has a first terminal coupled to the pull-up node PU, and a second terminal coupled to the first signal output terminal OUT.

The shift register 500 may further comprise a control circuit 503. The control circuit 503 may comprise a first control sub-circuit, a second control sub-circuit, and an adjustment sub-circuit. The first control sub-circuit comprises a third transistor M3, a fourth transistor M4, a seventh transistor M7, and an eighth transistor M8. The second control sub-circuit comprises a fifth transistor M5, a sixth transistor M6, a ninth transistor M9, and a tenth transistor M10. The adjustment sub-circuit comprises a first transistor M1 and a second transistor M2. The third transistor M3 has a control electrode coupled to the first power supply signal terminal VDDo, a first electrode coupled to the first power supply signal terminal VDDo, and a second electrode coupled to a first electrode of the fourth transistor M4. The fifth transistor M5 has a control electrode coupled to the second power supply signal terminal VDDe, a first electrode coupled to the second power supply signal terminal VDDe, and a second electrode coupled to a first electrode of the sixth transistor M6. The fourth transistor M4 has a control electrode coupled to the pull-up node PU, a first electrode coupled to the second electrode of the third transistor M3, and a second electrode coupled to the reference signal terminal VGL. The sixth transistor M6 has a control electrode coupled to the pull-up node PU, a first electrode coupled to the second electrode of the fifth transistor M5, and a second electrode coupled to the reference signal terminal VGL. The first transistor M1 has a control electrode coupled to the first control signal terminal CON1, a first electrode coupled to the first pull-down node PD1, and a second electrode coupled to the reference signal terminal VGL. The second transistor M2 has a control electrode coupled to the second control signal terminal CON2, a first electrode coupled to the second pull-down node PD2, and a second electrode coupled to the reference signal terminal VGL. The seventh transistor M7 has a control electrode coupled to the second electrode of the third transistor M3, a first electrode coupled to the first power supply signal terminal VDDo, and a second electrode coupled to the first pull-down node PD1. The ninth transistor M9 has a control electrode coupled to the second electrode of the fifth transistor M5, a first electrode coupled to the second power supply signal terminal VDDe, and a second electrode coupled to the second pull-down node PD2. The eighth transistor M8 has a control electrode coupled to the pull-up node PU, a first electrode coupled to the first pull-down node PD1, and a second electrode coupled to the reference signal terminal VGL. The tenth transistor M10 has a control electrode coupled to the pull-up node PU, a first electrode coupled to the second pull-down node PD2, and a second electrode coupled to the reference signal terminal VGL.

The shift register 500 may further comprise a pull-down circuit 504. The pull-down circuit 504 may comprise an eleventh transistor M11, a twelfth transistor M12, a thirteenth transistor M13, a fourteenth transistor M14, a fifteenth transistor M15, and a sixteenth transistor M16. The eleventh transistor M11 has a control electrode coupled to the first pull-down node PD1, a first electrode coupled to the pull-up node PU, and a second electrode coupled to the reference signal terminal VGL. The twelfth transistor M12 has a control electrode coupled to the second pull-down node PD2, a first electrode coupled to the pull-up node PU, and a second electrode coupled to the reference signal terminal VGL. The thirteenth transistor M13 has a control electrode coupled to the first pull-down node PD1, a first electrode coupled to the first signal output terminal OUT, and a second electrode coupled to the reference signal terminal VGL. The fourteenth transistor M14 has a control electrode coupled to the second pull-down node PD2, a first electrode coupled to the first signal output terminal OUT, and a second electrode coupled to the reference signal terminal VGL. The fifteenth transistor M15 has a control electrode coupled to the first pull-down node PD1, a first electrode coupled to the second signal output terminal OC, and a second electrode coupled to the reference signal terminal VGL. The sixteenth transistor M16 has a control electrode coupled to the second pull-down node PD2, a first electrode coupled to the second signal output terminal OC, and a second electrode coupled to the reference signal terminal VGL. In this embodiment, the output signal at the first signal output terminal OUT is only used to drive a display area, and the output signal at the second signal output terminal OC is used as an input signal of a next shift register unit.

The shift register 500 may further comprise a reset circuit 505. The reset circuit 505 may comprise a seventeenth transistor M17, and a nineteenth transistor M19. The seventeenth transistor M17 has a control electrode coupled to the first reset signal terminal RESET, a first electrode coupled to the pull-up node PU, and a second electrode coupled to the reference signal terminal VGL. The nineteenth transistor M19 has a control electrode coupled to a second reset signal terminal TRESET, a first electrode coupled to the pull-up node PU and a second electrode coupled to the reference signal terminal VGL. The first reset signal at the first reset signal terminal RESET is used to pull down the pull-up node PU and the first signal output terminal OUT in the shift register, to ensure normal output at the first signal output terminal OUT. Generally, during the operation of the shift register, since the clock signal terminal CLK is coupled to the pull-up node PU, the pull-up node PU generally has some noises. In order to prevent these noises from affecting an operation of a next frame, in general, the second reset signal at the second reset signal terminal TRESET may be used to perform general resetting after the end of the frame, for example, to reset all the shift registers of the gate driving circuit, thereby ensuring the stability of the shift registers.

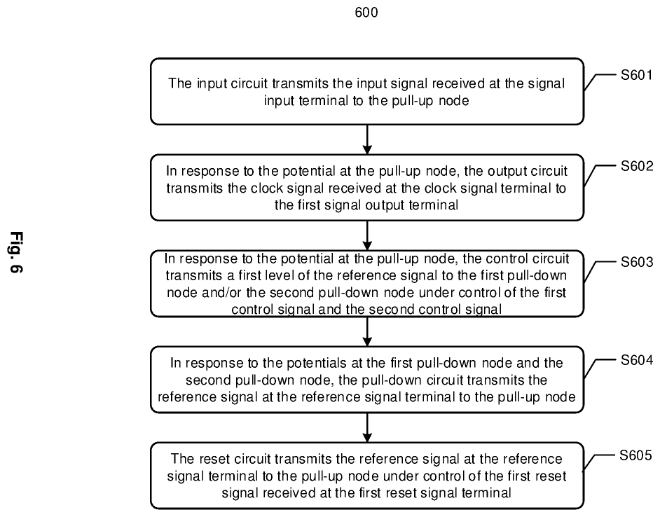

FIG. 6 illustrates a schematic flowchart of a method 600 of driving a shift register according to an embodiment of the present disclosure. The method 600 is applicable to the shift register in any of the above embodiments.

In step S601, the input circuit transmits the input signal received at the signal input terminal to the pull-up node.

In step S602, in response to the potential at the pull-up node, the output circuit transmits the clock signal received at the clock signal terminal to the first signal output terminal.

In step S603, in response to the potential at the pull-up node, the control circuit transmits a first level of the reference signal to the first pull-down node and/or the second pull-down node under control of the first control signal and the second control signal. For example, in a case where the pull-up node is at the first level, when the first power supply signal received at the first power supply signal terminal and the second power supply signal received at the second power supply signal terminal are switched, at least one of the first control signal received at the first control signal terminal and the second control signal received at the second control signal terminal is at a second level, so that the control circuit transmits the first level of the reference signal received at the reference signal terminal to the first pull-down node and/or the second pull-down node.

In step S604, in response to the potentials at the first pull-down node and the second pull-down node, the pull-down circuit transmits the reference signal at the reference signal terminal to the pull-up node.

In step S605, the reset circuit transmits the reference signal at the reference signal terminal to the pull-up node under control of the first reset signal received at the first reset signal terminal.

In one embodiment, the first control signal received at the first control signal terminal is the second power supply signal received at the second power supply signal terminal, and the second control signal received at the second control signal terminal is the first power supply signal received at the first power supply signal terminal.

In another embodiment, the first control signal received at the first control signal terminal and the second control signal received at the second control signal terminal are a third reset signal. In some embodiments, an effective level of the third reset signal occurs before the start of each frame. In some other embodiments, the effective level of the third reset signal occurs in response to transition of the first power supply signal or the second power supply signal. This enables the third reset signal to trigger the resetting of at least one of the first pull-down node and the second pull-down node before each frame or to trigger the resetting of at least one of the first pull-down node and the second pull-down node in response to a rising edge or a falling edge of the first power supply signal or the second power supply signal.

With the method of driving a shift register according to the present disclosure, it may enable the potential at at least one of the first pull-down node and the second pull-down node to be the first level of the reference signal when the first power supply signal and the second power supply signal are switched, instead of changing to the first level of the reference signal after a period of time, thereby ensuring not affecting the charging of the pull-up node.

Next, an operation of the shift register according to the embodiment of the present disclosure will be described in detail with reference to FIGS. 2, 6, and 7(b) to 7(d). For convenience of description, in the following example, description will be made by taking all switching transistors being N-type transistors, the first level being a low level, the second level being a high level, VDDe being switched from a high level to a low level, and VDDo being switched from a low level to a high level as an example.

FIG. 7(b) illustrates a schematic operation timing diagram of the shift register in FIG. 2. In this timing diagram, the second power supply signal received at the second power supply signal terminal VDDe serves as the first control signal received at the first control signal terminal, and the first power supply signal received at the first power supply signal terminal VDDo serves as the second control signal received at the second control signal terminal.

As shown in FIG. 7(b), during a time period t1, when the pull-up node is at a low level, the second power supply signal at the second power supply signal terminal VDDe is switched from a high level to a low level, and the first power supply signal at the first power supply signal terminal VDDo is switched from a low level to a high level, and accordingly, the first control signal (i.e., the second power supply signal) at the first control signal terminal CON1 is switched from a high level to a low level, and the second control signal (i.e., the first power supply signal) at the second control signal terminal CON2 is switched from a low level to a high level. Since the first power supply signal is at a high level, the third transistor M3 is turned on, and the high level at the first power supply signal terminal VDDo is transmitted to the first pull-down node PD1. Since the second control signal is at a high level, the second transistor M2 is turned on, and the low level received at the reference signal terminal VGL is transmitted to the second pull-down node PD2. Since the first pull-down node PD1 is at a high level and the second pull-down node PD2 is at a low level, only the eleventh transistor M11 among the eleventh transistor M11 and the twelfth transistor M12 is turned on, and the low level at the reference signal terminal VGL is transmitted to the pull-up node PU.

During a time period t2, the second power supply signal at the second power supply signal terminal VDDe and the first control signal are maintained at a low level, the first power supply signal at the first power supply signal terminal VDDo and the second control signal are maintained at a high level, the input signal INPUT is at a high level, the twenty-first transistor M21 is turned on, and the level at the pull-up node PU gradually rises from a low level through a pre-charging process. Since the pull-up node PU is at a high level, the twenty-second transistor M22 is turned on, and the clock signal at the clock signal terminal CLK is transmitted to the first signal output terminal OUT. In addition, since the pull-up node PU is at a high level, the fourth transistor M4 and the sixth transistor M6 are turned on, the low level at the reference signal terminal VGL is transmitted to the first pull-down node PD1 and the second pull-down node PD2 through the fourth transistor M4 and the sixth transistor M6 respectively, the first pull-down node PD1 becomes a low level, and the second pull-down node PD2 is still maintained at a low level.

During a time period t3, the second power supply signal at the second power supply signal terminal VDDe and the first control signal are maintained at a low level, the first power supply signal at the first power supply signal terminal VDDo and the second control signal are maintained at a high level, the input signal INPUT is at a low level, the twenty-first transistor M21 is turned off, and the level at the pull-up node PU continues to rise through a bootstrapping process of the capacitor C1. Since the pull-up node PU is at a high level, the fourth transistor M4 and the sixth transistor M6 are still turned on, and the first pull-down node PD1 and the second pull-down node PD2 are still maintained at a low level.

During a time period t4, the second power supply signal at the second power supply signal terminal VDDe and the first control signal are maintained at a low level, the first power supply signal at the first power supply signal terminal VDDo and the second control signal are maintained at a high level, and the first reset signal received at the first reset signal terminal RESET is at a high level. Since the first reset signal is at a high level, the seventeenth transistor M17 and the eighteenth transistor M18 are turned on, and the low level at the reference signal terminal VGL is transmitted to the pull-up node PU and the first signal output terminal OUT. Since the pull-up node PU is at a low level, the fourth transistor M4 and the sixth transistor M6 are turned off. At this time, since the first power supply signal is at a high level, the third transistor M3 is still turned on, and the high level of the first power supply signal is transmitted to the first pull-down node PD1. Since the second control signal is still at a high level, the second transistor M2 is still turned on. At this time, although the sixth transistor M6 is turned off, the low level at the reference signal terminal VGL may still be transmitted to the second pull-down node PD2. The second pull-down node PD2 is still maintained at a low level.

In general, a switching period of the first power supply signal and the second power supply signal (which are switched, for example, every 2 seconds) is much greater than that of a frame (which is switched, for example, every 16 milliseconds). In this way, a cycle of the multiple time periods t2, t3, and t4 elapses after a time period of t1, and then another cycle of the multiple time periods t2, t3, and t4 elapses after a time period of t1, and so on.

FIG. 7(c) illustrates another schematic operation timing diagram of the shift register in FIG. 2. In this timing diagram, a third reset signal STV0 serves as the first control signal received at the first control signal terminal and the second control signal received at the second control signal terminal. The third reset signal STV0 is triggered, for example, through a rising edge or a falling edge of the first power supply signal or the second power supply signal. As an example, FIG. 7(c) merely illustrates a case where the third reset signal STV0 serves as the first control signal received at the first control signal terminal and the second control signal received at the second control signal terminal, and the third reset signal STV0 is triggered through the rising edge of the first power supply signal.

As shown in FIG. 7(c), during a time period t1, when the pull-up node is at a low level, the second power supply signal at the second power supply signal terminal VDDe is switched from a high level to a low level, and the first power supply signal at the first power supply signal terminal VDDo is switched from a low level to a high level, and the first control signal at the first control signal terminal CON1 and the second control signal at the second control signal terminal CON2 (i.e., the third reset signal STV0) change to a high level due to the triggering at the rising edge of the first power supply signal. Since the first control signal and the second control signal are both at a high level, the first transistor and the second transistor are turned on, and the low level received at the reference signal terminal VGL is quickly transmitted to the first pull-down node PD1 and the second pull-down node PD2. Since the first pull-down node PD1 and the second pull-down node PD2 are both at a low level, both of the eleventh transistor M11 and the twelfth transistor M12 are turned off, thereby not affecting the charging of the pull-up node PU.

During a time period t2, the second power supply signal at the second power supply signal terminal VDDe is maintained at a low level, the first power supply signal at the first power supply signal terminal VDDo is maintained at a high level, the first control signal and the second control signal are at a low level, the input signal INPUT is at a high level, the twenty-first transistor M21 is turned on, and the level at the pull-up node PU gradually rises from a low level through a pre-charging process. Since the pull-up node PU is at a high level, the twenty-second transistor M22 is turned on, and the clock signal at the clock signal terminal CLK is transmitted to the first signal output terminal OUT. In addition, since the pull-up node PU is at a high level, the fourth transistor M4 and the sixth transistor M6 are turned on, the low level at the reference signal terminal VGL is transmitted to the first pull-down node PD1 and the second pull-down node PD2 through the fourth transistor M4 and the sixth transistor M6 respectively, the first pull-down node PD1 is maintained at a low level, and the second pull-down node PD2 is still maintained at a low level.

During a time period t3, the second power supply signal at the second power supply signal terminal VDDe is maintained at a low level, the first power supply signal at the first power supply signal terminal VDDo is maintained at a high level, the first control signal and the second control signal are maintained at a low level, the input signal INPUT is at a low level, the twenty-first transistor M21 is turned off, and the level at the pull-up node PU continues to rise through a bootstrapping process of the capacitor C1. Since the pull-up node PU is at a high level, the fourth transistor M4 and the sixth transistor M6 are still turned on, and the first pull-down node PD1 and the second pull-down node PD2 are still maintained at a low level.

During a time period t4, the second power supply signal at the second power supply signal terminal VDDe is maintained at a low level, the first power supply signal at the first power supply signal terminal VDDo is maintained at a high level, the first control signal and the second control signal are maintained at a low level, and the first reset signal received at the first reset signal terminal RESET is at a high level. Since the first reset signal is at a high level, the seventeenth transistor M17 and the eighteenth transistor M18 are turned on, and the low level at the reference signal terminal VGL is transmitted to the pull-up node PU. Since the pull-up node PU is at a low level, the fourth transistor M4 and the sixth transistor M6 are turned off. At this time, since the first power supply signal VDDo is at a high level and the first control signal is at a low level, the third transistor M3 is still turned on, and the first transistor M1 is turned off, so that the first pull-down node PD1 is pulled up to the high level at the first power supply signal terminal VDDo. Since the second power supply signal is at a low level and the second control signal is at a low level, both of the fifth transistor M5 and the second transistor M2 are turned off, and the second pull-down node PD2 is still maintained at a low level.

In this embodiment, the third reset signal is triggered by the rising edge or the falling edge of the first power supply signal or the second power supply signal. Therefore, the change of the third reset signal (i.e., the first control signal and the second control signal) corresponds to the change of the first power supply signal or the second power supply signal. Further, a switching period of the first power supply signal and the second power supply signal (which are switched, for example, every 2 seconds) is much greater than that of a frame (which is switched, for example, every 16 milliseconds). Therefore, this embodiment may be the same as that illustrated in FIG. 7(b), and a cycle of the multiple time periods t2, t3, and t4 elapses after a time period of t1, and then another cycle of the multiple time periods t2, t3, and t4 elapses after a time period of t1, and so on.

FIG. 7(d) illustrates another schematic operation timing diagram of the shift register in FIG. 2. In this timing diagram, a third reset signal STV0 serves as the first control signal received at the first control signal terminal and the second control signal received at the second control signal terminal. An effective level of the third reset signal STV0 occurs before the start of each frame. As an example, FIG. 7(d) illustrates a case where the third reset signal STV0 serves as the first control signal received at the first control signal terminal and the second control signal received at the second control signal terminal.

As shown in FIG. 7(d), during a time period t1, the pull-up node is at a low level, the second power supply signal at the second power supply signal terminal VDDe is switched from a high level to a low level, and the first power supply signal at the first power supply signal terminal VDDo is switched from a low level to a high level, and the first control signal at the first control signal terminal CON1 and the second control signal at the second control signal terminal CON2 (i.e., the third reset signal STV0) are at a high level, and then a frame may start. Since the first control signal and the second control signal are both at a high level, the first transistor and the second transistor are turned on, and the low level received at the reference signal terminal VGL is quickly transmitted to the first pull-down node PD1 and the second pull-down node PD2. Since the first pull-down node PD1 and the second pull-down node PD2 are both at a low level, both of the eleventh transistor M11 and the twelfth transistor M12 are turned off, thereby not affecting the charging of the pull-up node PU.

During a time period t2, the second power supply signal at the second power supply signal terminal VDDe is maintained at a low level, the first power supply signal at the first power supply signal terminal VDDo is maintained at a high level, the first control signal and the second control signal are at a low level, the input signal INPUT is at a high level, the twenty-first transistor M21 is turned on, and the level at the pull-up node PU gradually rises from a low level through a pre-charging process. Since the pull-up node PU is at a high level, the twenty-second transistor M22 is turned on, and the clock signal at the clock signal terminal CLK is transmitted to the first signal output terminal OUT. In addition, since the pull-up node PU is at a high level, the fourth transistor M4 and the sixth transistor M6 are turned on, the low level at the reference signal terminal VGL is transmitted to the first pull-down node PD1 and the second pull-down node PD2 through the fourth transistor M4 and the sixth transistor M6 respectively, the first pull-down node PD1 is maintained at a low level, and the second pull-down node PD2 is still maintained at a low level.

During a time period t3, the second power supply signal at the second power supply signal terminal VDDe is maintained at a low level, the first power supply signal at the first power supply signal terminal VDDo is maintained at a high level, the first control signal and the second control signal are maintained at a low level, the input signal INPUT is at a low level, the twenty-first transistor M21 is turned off, and the level at the pull-up node PU continues to rise through a bootstrapping process of the capacitor C1. Since the pull-up node PU is at a high level, the fourth transistor M4 and the sixth transistor M6 are still turned on, and the first pull-down node PD1 and the second pull-down node PD2 are still maintained at a low level.

During a time period t4, the second power supply signal at the second power supply signal terminal VDDe is maintained at a low level, the first power supply signal at the first power supply signal terminal VDDo is maintained at a high level, the first control signal and the second control signal are maintained at a low level, and the first reset signal received at the first reset signal terminal RESET is at a high level. Since the first reset signal is at a high level, the seventeenth transistor M17 and the eighteenth transistor M18 are turned on, and the low level at the reference signal terminal VGL is transmitted to the pull-up node PU. Since the pull-up node PU is at a low level, the fourth transistor M4 and the sixth transistor M6 are turned off. At this time, since the first power supply signal VDDo is at a high level and the first control signal is at a low level, the third transistor M3 is still turned on, and the first transistor M1 is turned off, so that the first pull-down node PD1 is pulled up to the high level at the first power supply signal terminal VDDo. Since the second power supply signal is at a low level and the second control signal is at a low level, both of the fifth transistor M5 and the second transistor M2 are turned off, and the second pull-down node PD2 is still maintained at a low level.

In this embodiment, the effective level of the third reset signal occurs before the start of each frame. Therefore, the effective level of the third reset signal (i.e., the first control signal and the second control signal) arrives before an effective level of an input signal of a first row of shift register. Further, a switching period of the first power supply signal and the second power supply signal (which are switched, for example, every 2 seconds) is much greater than that of a frame (which is switched, for example, every 16 milliseconds). Therefore, in this embodiment, each switching between the first power supply signal and the second power supply signal may last for multiple cycles of the time period t1, t2, t3 and t4. Compared with the embodiment shown in FIG. 7(b) and FIG. 7(c), in the embodiment of FIG. 7(d), more cycles (each of which comprises the time periods t1, t2, t3 and t4) may elapse, and the potential at at least one of the first pull-down node and the second pull-down node is set to the first level of the reference signal before each frame starts, which thus results in greater power consumption but higher reliability in this embodiment.

By comparing the timing diagram shown in FIG. 7(a) in the related art with the timing diagrams shown in FIGS. 7(b) to 7(d) according to the embodiments of the present disclosure, the method of driving a shift register according to the present disclosure may enable the potential at at least one of the first pull-down node and the second pull-down node to be the first level of the reference signal (as shown by the time periods t1 in FIGS. 7(b) to 7(d)) when the first power supply signal and the third power supply are switched, instead of changing to the first level of the reference signal after a period of time (as shown by the time period t1 in FIG. 7(a)), thereby ensuring not affecting the charging of the pull-up node.

Based on the detailed description of FIGS. 2 and 7(b) to 7(d), it may be easily understood by those skilled in the art that the operation timings of the shift register shown in FIG. 3, FIG. 4, and FIG. 5 are similar to that shown in FIG. 2, and therefore will not be repeated here.

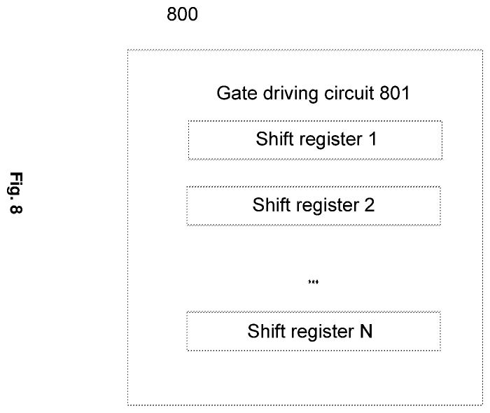

FIG. 8 illustrates a schematic block diagram of a display apparatus 800 according to an embodiment of the present disclosure. The display apparatus 800 according to the embodiment of the present disclosure may be any product or component having a display function such as an electronic paper, a mobile phone, a tablet computer, a television, a display, a notebook computer, a digital photo frame, a navigator, etc.

As shown in FIG. 8, the display apparatus 800 may comprise a gate driving circuit 810 according to an embodiment of the present disclosure. The gate driving circuit 801 may comprise cascaded N shift registers according to the embodiment of the present disclosure (for example, the shift registers shown in FIG. 2, FIG. 3, FIG. 4, and FIG. 5), that is, the shift register 1, the shift register 2, . . . , and the shift register N, wherein N is a positive integer.

With the gate driving circuit and the display apparatus according to the present disclosure, it may enable the potential at at least one of the first pull-down node and the second pull-down node to be the first level of the reference signal when the first power supply signal and the second power supply signal are switched, instead of changing to the first level of the reference signal after a period of time, thereby ensuring not affecting the charging of the pull-up node.

The specific embodiments described above further describe the purpose, technical solutions, and beneficial effects of the embodiments of the present disclosure in detail. It should be understood that the above description is only specific embodiments of the embodiments of the present disclosure, and is not intended to limit the present disclosure. Any modifications, equivalent replacements, improvements, etc., shall be contained in the scope of protection of the present disclosure without departing from the spirit and principles of the present disclosure.

1. A shift register, comprising:
an input circuit coupled to a signal input terminal and a pull-up node of the shift register, and configured to transmit an input signal received at the signal input terminal to the pull-up node;
an output circuit coupled to a first signal output terminal and a clock signal terminal, and configured to transmit a clock signal received at the clock signal terminal to the first signal output terminal in response to a potential at the pull-up node;
a reset circuit coupled to a first reset signal terminal, a reference signal terminal and the pull-up node, and configured to transmit a reference signal at the reference signal terminal to the pull-up node under control of a first reset signal received at the first reset signal terminal;
a control circuit coupled to the pull-up node, the reference signal terminal, a first power supply signal terminal, a second power supply signal terminal, a first control signal terminal and a second control signal terminal, and configured to transmit the reference signal received at the reference signal terminal to a first pull-down node and/or a second pull-down node of the shift register under control of a first control signal received at the first control signal terminal and a second control signal received at the second control signal terminal in response to the potential at the pull-up node; and
a pull-down circuit coupled to the first pull-down node and the second pull-down node, and configured to transmit the reference signal at the reference signal terminal to the pull-up node in response to potentials at the first pull-down node and the second pull-down node.

2. The shift register according to claim 1, wherein the control circuit comprises:
a first control sub-circuit coupled to the first power supply signal terminal, the pull-up node and the first pull-down node, and configured to control the potential at the first pull-down node based on the first power supply signal received at the first power supply signal terminal in response to the potential at the pull-up node;
a second control sub-circuit coupled to the second power supply signal terminal, the pull-up node and the second pull-down node, and configured to control the potential at the second pull-down node based on the second power supply signal received at the second power supply signal terminal in response to the potential at the pull-up node; and
an adjustment sub-circuit coupled to the first control signal terminal, the second control signal terminal, the first pull-down node, the second pull-down node and the reference signal terminal, and configured to transmit the reference signal received at the reference signal terminal to the first pull-down node under control of the first control signal received at the first control signal terminal, and transmit the reference signal received at the reference signal terminal to the second pull-down node under control of the second control signal received at the second control signal terminal.

3. The shift register according to claim 2, wherein the adjustment sub-circuit comprises:
a first transistor having a control electrode coupled to the first control signal terminal, a first electrode coupled to the first pull-down node, and a second electrode coupled to the reference signal terminal; and
a second transistor having a control electrode coupled to the second control signal terminal, a first electrode coupled to the second pull-down node, and a second electrode coupled to the reference signal terminal.

4. The shift register according to claim 1, wherein the first control signal terminal is coupled to the second power supply signal terminal, and the second control signal terminal is coupled to the first power supply signal terminal.

5. The shift register according to claim 1, wherein the first control signal terminal and the second control signal terminal are coupled to each other.

6. The shift register according to claim 1, wherein the first control sub-circuit comprises a third transistor and a fourth transistor, and the second control sub-circuit comprises a fifth transistor and a sixth transistor, wherein
the third transistor has a control electrode coupled to the first power supply signal terminal, a first electrode coupled to the first power supply signal terminal, and a second electrode coupled to the first pull-down node;
the fifth transistor has a control electrode coupled to the second power supply signal terminal, a first electrode coupled to the second power supply signal terminal, and a second electrode coupled to the second pull-down node;
the fourth transistor has a control electrode coupled to the pull-up node, a first electrode coupled to the first pull-down node, and a second electrode coupled to the reference signal terminal; and
the sixth transistor has a control electrode coupled to the pull-up node, a first electrode coupled to the second pull-down node, and a second electrode coupled to the reference signal terminal.

7. The shift register according to claim 1, wherein the first control sub-circuit comprises a third transistor, a fourth transistor, a seventh transistor, and an eighth transistor, and the second control sub-circuit comprises a fifth transistor, a sixth transistor, a ninth transistor and a tenth transistor, wherein
the third transistor has a control electrode coupled to the first power supply signal terminal, a first electrode coupled to the first power supply signal terminal, and a second electrode coupled to a first electrode of the fourth transistor;
the fifth transistor has a control electrode coupled to the second power supply signal terminal, a first electrode coupled to the second power supply signal terminal, and a second electrode coupled to a first electrode of the sixth transistor;
the fourth transistor has a control electrode coupled to the pull-up node, a first electrode coupled to the second electrode of the third transistor, and a second electrode coupled to the reference signal terminal;
the sixth transistor has a control electrode coupled to the pull-up node, a first electrode coupled to the second electrode of the fifth transistor, and a second electrode coupled to the reference signal terminal;
the seventh transistor has a control electrode coupled to the second electrode of the third transistor, a first electrode coupled to the first power supply signal terminal, and a second electrode coupled to the first pull-down node;
the ninth transistor has a control electrode coupled to the second electrode of the fifth transistor, a first electrode coupled to the second power supply signal terminal, and a second electrode coupled to the second pull-down node;
the eighth transistor has a control electrode coupled to the pull-up node, a first electrode coupled to the first pull-down node, and a second electrode coupled to the reference signal terminal; and
the tenth transistor has a control electrode coupled to the pull-up node, a first electrode coupled to the second pull-down node, and a second electrode coupled to the reference signal terminal.

8. The shift register according to claim 1, wherein the pull-down circuit comprises an eleventh transistor, a twelfth transistor, a thirteenth transistor, and a fourteenth transistor, wherein
the eleventh transistor has a control electrode coupled to the first pull-down node, a first electrode coupled to the pull-up node, and a second electrode coupled to the reference signal terminal;
the twelfth transistor has a control electrode coupled to the second pull-down node, a first electrode coupled to the pull-up node, and a second electrode coupled to the reference signal terminal;
the thirteenth transistor has a control electrode coupled to the first pull-down node, a first electrode coupled to the first signal output terminal, and a second electrode coupled to the reference signal terminal; and
the fourteenth transistor has a control electrode coupled to the second pull-down node, a first electrode coupled to the first signal output terminal, and a second electrode coupled to the reference signal terminal.

9. The shift register according to claim 1, wherein the pull-down circuit comprises an eleventh transistor, a twelfth transistor, a thirteenth transistor, a fourteenth transistor, a fifteenth transistor, and a sixteenth transistor, wherein
the eleventh transistor has a control electrode coupled to the first pull-down node, a first electrode coupled to the pull-up node, and a second electrode coupled to the reference signal terminal;
the twelfth transistor has a control electrode coupled to the second pull-down node, a first electrode coupled to the pull-up node, and a second electrode coupled to the reference signal terminal;
the thirteenth transistor has a control electrode coupled to the first pull-down node, a first electrode coupled to the first signal output terminal, and a second electrode coupled to the reference signal terminal;
the fourteenth transistor has a control electrode coupled to the second pull-down node, a first electrode coupled to the first signal output terminal, and a second electrode coupled to the reference signal terminal;
the fifteenth transistor has a control electrode coupled to the first pull-down node, a first electrode coupled to a second signal output terminal of the shift register unit, and a second electrode coupled to the reference signal terminal; and
the sixteenth transistor has a control electrode coupled to the second pull-down node, a first electrode coupled to the second signal output terminal, and a second electrode coupled to the reference signal terminal.

10. The shift register according to claim 1, wherein the reset circuit comprises a seventeenth transistor and an eighteenth transistor, wherein,
the seventeenth transistor has a control electrode coupled to the first reset signal terminal, a first electrode coupled to the pull-up node, and a second electrode coupled to the reference signal terminal; and
the eighteenth transistor has a control electrode coupled to the first reset signal terminal, a first electrode coupled to the first signal output terminal, and a second electrode coupled to the reference signal terminal.

11. The shift register according to claim 1, wherein the reset circuit comprises a seventeenth transistor having a control electrode coupled to the first reset signal terminal, a first electrode coupled to the pull-up node, and a second electrode coupled to the reference signal terminal.

12. The shift register according to claim 1, wherein the reset circuit comprises a seventeenth transistor, a nineteenth transistor, and a twentieth transistor, wherein
the seventeenth transistor has a control electrode coupled to the first reset signal terminal, a first electrode coupled to the pull-up node, and a second electrode coupled to the reference signal terminal;
the nineteenth transistor has a control electrode coupled to the second reset signal terminal, a first electrode coupled to the pull-up node, and a second electrode coupled to the reference signal terminal; and
the twentieth transistor has a control electrode coupled to the second reset signal terminal, a first electrode coupled to the first signal output terminal, and a second electrode coupled to the reference signal terminal.

13. The shift register according to claim 1, wherein the reset circuit comprises a seventeenth transistor and a nineteenth transistor, wherein
the seventeenth transistor has a control electrode coupled to the first reset signal terminal, a first electrode coupled to the pull-up node, and a second electrode coupled to the reference signal terminal; and
the nineteenth transistor has a control electrode coupled to the second reset signal terminal, a first electrode coupled to the pull-up node, and a second electrode coupled to the reference signal terminal.

14. The shift register according to claim 1, wherein the input circuit comprises a twenty-first transistor having a control electrode coupled to a signal input terminal, a first electrode coupled to the signal input terminal, and a second electrode coupled to the pull-up node.

15. The shift register according to claim 1, wherein the output circuit comprises a twenty-second transistor and a capacitor, wherein
the twenty-second transistor has a control electrode coupled to the pull-up node, a first electrode coupled to the clock signal terminal, and a second electrode coupled to the first signal output terminal; and
the capacitor has a first terminal coupled to the pull-up node, and a second terminal coupled to the first signal output terminal, or
the output circuit comprises a twenty-second transistor, a twenty-third transistor, and a capacitor, wherein
the twenty-second transistor has a control electrode coupled to the pull-up node, a first electrode coupled to the clock signal terminal, and a second electrode coupled to the first signal output terminal;
the twenty-third transistor has a control electrode coupled to the pull-up node, a first electrode coupled to the clock signal terminal, and a second electrode coupled to the second signal output terminal of the shift register; and
the capacitor has a first terminal coupled to the pull-up node, and a second terminal coupled to the first signal output terminal.

16. (canceled)

17. A gate driving circuit, comprising a plurality of cascaded shift registers according to claim 1.

18. A display apparatus comprising the gate driving circuit according to claim 17.

19. A method of driving the shift register according to claim 1, comprising:
transmitting, by the input circuit, the input signal received at the signal input terminal to the pull-up node;
in response to the potential at the pull-up node, transmitting, by the output circuit, the clock signal received at the clock signal terminal to the first signal output terminal;
in response to the potential at the pull-up node, transmitting, by the control circuit, a first level of the reference signal to the first pull-down node and/or the second pull-down node under control of the first control signal and the second control signal;
in response to the potentials at the first pull-down node and the second pull-down node, transmitting, by the pull-down circuit, the reference signal at the reference signal terminal to the pull-up node; and
transmitting, by the reset circuit, the reference signal at the reference signal terminal to the pull-up node under control of the first reset signal received at the first reset signal terminal.

20. The method according to claim 19, wherein the first control signal received at the first control signal terminal is the second power supply signal received at the second power supply signal terminal, and the second control signal received at the second control signal terminal is the first power supply signal received at the first power supply signal terminal, or
wherein the first control signal received at the first control signal terminal and the second control signal received at the second control signal terminal are both a third reset signal.

21. (canceled)

22. The method according to claim 20, wherein an effective level of the third reset signal occurs before the start of each frame, or
an effective level of the third reset signal occurs in response to transition of the first power supply signal or the second power supply signal.

23. (canceled)
